(19) United States
(12) Patent Application Publication
(10) Pub. No.: US 2024/0355713 A1
(43) Pub. Date: Oct. 24, 2024

(54) SEMICONDUCTOR DEVICE

(71) Applicant: FUJI ELECTRIC CO., LTD., Kawasaki-shi (JP)

(72) Inventor: Yushi SATO, Kawasaki-shi (JP)

(73) Assignee: FUJI ELECTRIC CO., LTD., Kawasaki-shi (JP)

(21) Appl. No.: 18/589,156

(22) Filed: Feb. 27, 2024

(30) Foreign Application Priority Data
Apr. 18, 2023 (JP) 2023-067564

(51) Int. Cl. H01L 23/495; H01L 29/739

(52) U.S. Cl. CPC H01L 23/49548; H01L 29/7393

(57) ABSTRACT

A semiconductor device includes a substrate with one side and another side in a first direction parallel to a surface thereof and including a semiconductor element provided thereon, and first and second main terminals located at the one side of the substrate, side by side a second direction parallel to the surface of the substrate and orthogonal to the first direction. The first and second main terminals respectively include first and second external connection portions respectively connected to separate external conductors, and respectively include first and second narrow portions connected to the substrate. In the second direction, widths of the first and second narrow portions are respectively less than widths of the first and second external connection portions. Centers of the first and second narrow portions are located closer respectively to the second and first main terminals than are centers of the first and second external connection portions.

### CROSS-REFERENCE TO RELATED APPLICATION

This application is based upon and claims the benefit of priority to Japanese Patent Application No. 2023-067564, Filed on Apr. 18, 2023, the entire contents of which are incorporated herein by reference.

### BACKGROUND OF THE INVENTION

### 1. Technical Field

The present invention relates to a semiconductor device including a substrate having a semiconductor element and a plurality of main terminals.

### 2. Description of the Related Art

A conventional semiconductor device includes a substrate provided with a semiconductor element, such as an insulated gate bipolar transistor (IGBT). In this type of semiconductor device, a main terminal such as a positive electrode terminal and a negative electrode terminal connected to an external conductor is disposed on one side of a substrate (see, for example, JP 2021-120975 A, WO 2021/033565 A, and WO 2013/128787 A).

In the semiconductor device, when the main circuit inductance increases, a problem such as generation of a surge voltage occurs. Accordingly, there is also a problem that a structure of a semiconductor element capable of securing high voltage and heat resistance is required.

In addition, since the main terminals such as the positive electrode terminal and the negative electrode terminal are connected to the substrate, the circuit layer on the substrate is enlarged as the width of the main terminal is wider, and the semiconductor device is increased in size.

An object of the present invention is to provide a semiconductor device capable of simplifying a structure and reducing inductance.

### SUMMARY OF THE INVENTION

According to one aspect, a semiconductor device includes: a substrate including a semiconductor element; and a first main terminal and a second main terminal located on one side in a first direction parallel to a mounting face of the semiconductor element on the substrate, in which the first main terminal includes a first external connection portion connected to an external conductor and a first narrow portion connected to the substrate, the first narrow portion having a width in a second direction parallel to the mounting face and orthogonal to the first direction smaller than a width of the first external connection portion, the second main terminal includes a second external connection portion connected to an external conductor and a second narrow portion connected to the substrate, the second narrow portion having a width in the second direction smaller than a width of the second external connection portion, a center of the first narrow portion in the second direction is located closer to the second main terminal than a center of the first external connection portion in the second direction is, and a center of the second narrow portion in the second direction is located closer to the first main terminal than a center of the second external connection portion in the second direction is.

According to the above aspect, the structure can be simplified, and the inductance can be reduced.

### BRIEF DESCRIPTION OF THE DRAWINGS

FIG. 1 is a plan view of a schematic configuration of a semiconductor device according to one embodiment;

FIG. 2 is a cross-sectional view of a schematic configuration of a semiconductor device according to one embodiment;

FIG. 3 is a plan view of a main terminal and a unit module according to one embodiment;

FIG. 4 is a plan view indicating size of each part of the main terminal according to one embodiment;

FIG. 5 is a front view of the main terminals (a P terminal and an N terminal) according to a modification of one embodiment;

FIG. 6 is a diagram indicating a relationship between an inter-terminal distance and inductance in one embodiment and a comparative example;

FIG. 7 is a diagram indicating a relationship between a terminal width and inductance in one embodiment; and

FIG. 8 is a diagram indicating a relationship between a terminal thickness and inductance in one embodiment.

### DETAILED DESCRIPTION

A semiconductor device according to an embodiment of the present invention will be described below with reference to the drawings. Note that the present invention is not limited to the embodiment described below, and can be appropriately modified and implemented within the scope not changing the gist thereof.

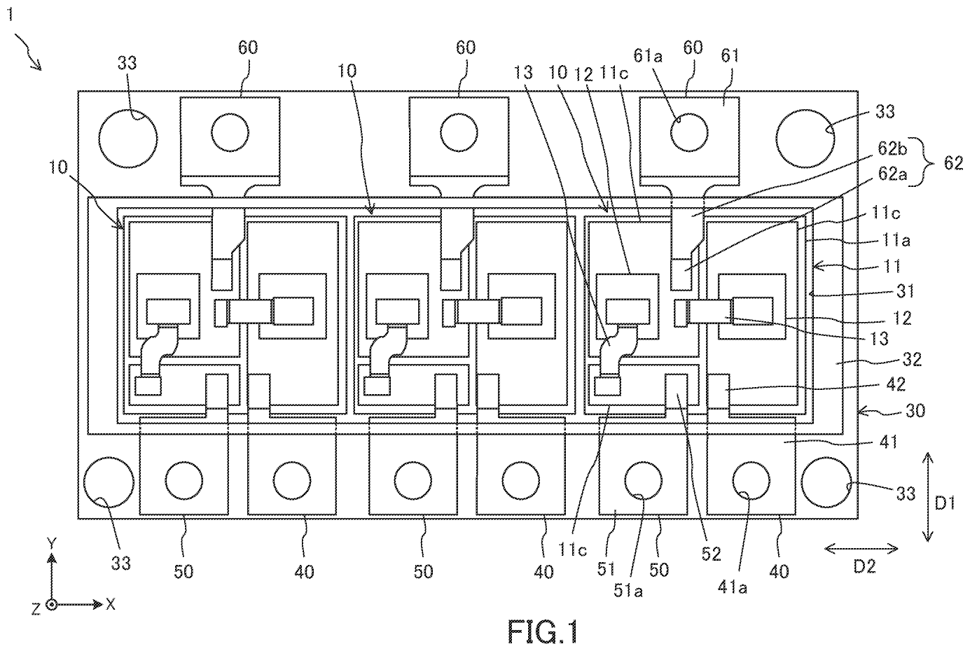

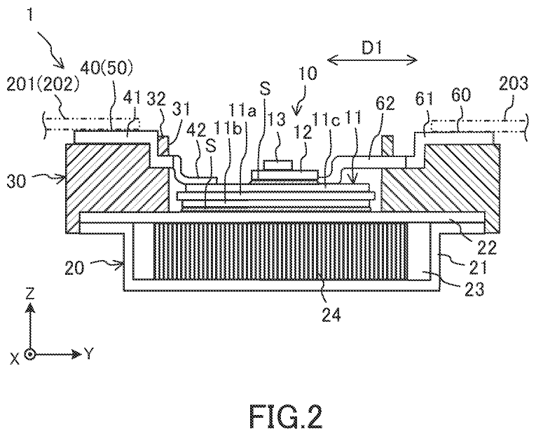

FIGS. 1 and 2 are a plan view and a cross-sectional view of a schematic configuration of a semiconductor device 1 according to one embodiment.

Note that, from among X, Y, and Z directions indicated in FIGS. 1 and 2 and FIGS. 3 to 5 to be described later, the Z direction is defined as the up-down direction of the semiconductor device 1 (thickness direction of a substrate 11). The X and Y directions orthogonal to the Z direction are defined, respectively, as the longitudinal direction of the semiconductor device 1 and the lateral direction of the semiconductor device 1, respectively. In some cases, the X direction may be referred to as a right-left direction, the Y direction may be referred to as a front-rear direction, and the Z direction may be referred to as an up-down direction. Such directional terms are used for convenience of description. Thus, depending of the posture of attachment of the semiconductor device 1, the correspondence relationship with the X, Y, and Z directions varies.

The semiconductor device 1 according to the present embodiment is applied, for example, to a power converter, such as a power control unit, and serves as a power semiconductor module for an inverter circuit. The semiconductor device 1 is used, for example, in a traction inverter for an electric vehicle.

The semiconductor device 1 illustrated in FIGS. 1 and 2 includes three unit modules 10, a cooler 20 that cools the unit modules 10 (refer to FIG. 2), a case 30 that houses three unit modules 10, and sealing resin (not illustrated) injected in the case 30.

The unit module 10 includes the substrate 11 and a semiconductor element 12 disposed on the substrate 11. In the present embodiment, the three unit modules 10 are disposed J by side in the X direction. The three unit modules 10 achieve, for example, U, V, and W phases, resulting in formation of a three-phase inverter circuit. Note that the unit modules 10 may be each referred to as a power cell or semiconductor unit. The number of unit modules 10 to be disposed is at least one.

The substrate 11 illustrated in FIG. 2 includes, for example, a direct copper bonding (DCB) substrate, an active metal brazing (AMB) substrate, or a metal base substrate. For example, the substrate 11 includes an insulator 11a, a heat dissipator 11b disposed on the lower face of the insulator 11a, and a plurality of circuit boards 11c disposed on the upper face of the insulator 11a. For example, the substrate 11 is rectangular in shape in plan view.

For example, the insulator 11a is formed of an insulating material, such as a ceramic material (e.g., alumina (Al₂O₃), aluminum nitride (AlN), or silicon nitride (Si₃N₄)), a resin material (e.g., epoxy), or an epoxy resin material with a ceramic material as a filler. Note that the insulator 11a may be referred to as an insulating layer or an insulating film.

The heat dissipator 11b has a predetermined thickness in the Z direction and is formed on the lower face of the insulator 11a. For example, the heat dissipator 11b is made of a metal plate having good thermal conductivity, such as copper and aluminum. The heat dissipator 11b is bonded to an upper face of the cooler 20 (top plate 22) by a bonding material such as solder S.

Three circuit boards 11c are formed on the upper face of the insulator 11a. The number of circuit boards 11c formed on the upper face of the insulator 11a may be any number of one or more. The circuit boards 11c are metal layers such as copper foils, and are formed in island shapes in a mutually electrically isolated state on the insulator 11a. Note that the circuit boards 11c may be each referred to as a circuit layer.

As illustrated in FIG. 2, the semiconductor element 12 (emitter electrode) is disposed on a mounting face, which is an upper face of the substrate 11 (circuit board 11c), via solder S. In FIG. 1, two semiconductor elements 12 are illustrated per single substrate 11, but the number of semiconductor elements 12 is arbitrary. For example, the semiconductor elements 12 are each achieved with a semiconductor substrate based on silicon (Si), silicon carbide (SiC), gallium nitride (GaN), or diamond, and are each square or rectangular in shape in plan view.

Note that the semiconductor element 12 include a switching element such as an insulated gate bipolar transistor (IGBT) or a power metal oxide semiconductor field effect transistor (MOSFET), and a diode such as a free wheeling diode (FWD). Such a switching element and a diode may be made in antiparallel connection. As the semiconductor element 12, used may be a reverse conducting (RC)-IGBT element of an IGBT and an FWD in unification, a power MOSFET element, or a reverse blocking (RB)-IGBT element highly resistant to a reverse bias. In particular, since the RC-IGBT element can downsize the internal circuit by bidirectional energization, further downsizing can be expected when combined with the present embodiment that can downsize the semiconductor device 1 (substrate 11) as described later.

An emitter electrode of the semiconductor element 12 is in electrically conductive connection with a predetermined circuit board 11c through a metal wiring board 13. For example, the metal wiring board 13 is made of a metal material, such as copper material, copper-alloy-based material, aluminum-alloy-based material, or iron-alloy-based material, and is formed due to folding by pressing or the like. For example, the semiconductor element 12 and the metal wiring board 13 are joined together through a binder, such as solder. The metal wiring board 13 may be referred to as a lead frame. Note that, instead of the metal wiring board 13, a connecting member, such as a conductive wire, may be disposed.

The case 30 is formed in a rectangular frame shape and has an opening 31 in the center thereof. The three unit modules 10 described above are housed in the opening 31 rectangular in shape. That is, the three unit modules 10 are housed in the space defined by the frame-shaped case 30. Although it is an example, a wall portion 32 is provided to surround the opening 31 of the case 30. The wall portion 32 rises to a predetermined height.

As illustrated in FIG. 1, the case 30 is provided with main terminals (a P terminal 40, an N terminal 50, and an M terminal 60) that function as external connection terminals for connection with external conductors 201, 202, 203 (see two-dot chain lines in FIG. 2), and a control terminal for control (not illustrated). One P terminal 40, one N terminal 50, and one M terminal 60 are arranged for each unit module 10. The P terminal 40 is an example of a first main terminal, the N terminal 50 is an example of a second main terminal, and the M terminal 60 is an example of a third main terminal.

The P terminal 40 and the N terminal 50 are located on the negative side in the Y direction with respect to the substrate 11. In other words, the P terminal 40 and the N terminal 50 are located on one side in the first direction D1 (Y direction) parallel to the mounting face of the semiconductor element 12 on the substrate 11 (XY plane which is the upper face of the circuit board 11c) with respect to the substrate 11.

On the other hand, the M terminal 60 is located on the positive side in the Y direction with respect to the substrate 11. In other words, the M terminal 60 is located on the side opposite to the P terminal 40 and the N terminal 50 in the first direction D1 with respect to the substrate 11.

For example, the P terminal 40, the N terminal 50, and the M terminal 60 are made of a metal material, such as copper material, copper-alloy-based material, aluminum-alloy-based material, or iron-alloy-based material, and are preferably formed due to folding by pressing or the like.

The P terminal 40 includes a first external connection portion 41 connected to the external conductor 201 and a first narrow portion 42 having a width narrower than that of the first external connection portion 41 and connected to the substrate 11. Here, although the width of each part will be described later, the width of each part is the width in the second direction D2 (X direction) parallel to the mounting face of the semiconductor element 12 on the substrate 11 (XY plane which is the upper face of the circuit board 11c) and orthogonal to the first direction D1.

The N terminal 50 includes a second external connection portion 51 connected to the external conductor 202 and a second narrow portion 52 having a width narrower than that of the second external connection portion 51 and connected to the substrate 11.

The M terminal 60 includes a third external connection portion 61 connected to the external conductor 203 and a third narrow portion 62 having a width narrower than that of the third external connection portion 61 and connected to the substrate 11. In the third narrow portion 62 of the M terminal 60, the width of a tip portion 62a connected to the substrate 11 is further narrower than the width of an intermediate portion 62b positioned between the tip portion 62a and the third external connection portion 61.

Each of the P terminal 40, the N terminal 50, and the M terminal 60 is preferably connected onto the circuit board 11c by ultrasonic bonding, for example, in each of the narrow portions 42, 52, and 62. Note that each of the P terminal 40, the N terminal 50, and the M terminal 60 may be connected onto the circuit board 11c by other joining means (connecting means) such as laser welding or soldering.

The P terminal 40 may be each referred to as a positive terminal (input terminal). The N terminal 50 may be each referred to as a negative terminal (output terminal). The M terminal 60 may be each referred to as an intermediate terminal (output terminal). The external connection portions 41, 51, and 61 of the P terminal 40, the N terminal 50, and the M terminal 60 are connected to the external conductor 201, 202, and 203 illustrated in FIG. 2 by, for example, fastening in the screw holes 41a, 51a, and 61a.

As an example, as shown in FIGS. 1 and 2, the P terminal 40 and the N terminal 50 are bent vertically downward from horizontal on the first narrow portion 42 side and the second narrow portion 52 side with respect to the screw holes 41a and 51a of the first external connection portion 41 and the second external connection portion 51, and are bent to be horizontal again to penetrate the wall portion 32. Further, the P terminal 40 and the N terminal 50 are bent vertically downward from the horizontal direction in the first narrow portion 42 and the second narrow portion 52, and bent to be horizontal again to be connected to the circuit board 11c. In addition, the M terminal 60 is bent vertically downward from the horizontal direction on the third narrow portion 62 side with respect to the screw hole 61a of the third external connection portion 61, and is bent to be horizontal again to penetrate the wall portion 32. Further, the M terminal 60 is bent vertically downward in the third narrow portion 62 on the substrate 11, and is bent to be horizontal again to be connected to the circuit board 11c.

The case 30 has a plurality of through holes 33 along its outer peripheral edge. For example, the through holes 33 each serve as a hole for insertion of a screw for fixing the semiconductor device 1 and an external device such as an inverter (not illustrated) together.

Note that, for example, as resin for the case 30, any insulating resin can be selected from polyphenylene sulfide (PPS), polybutylene terephthalate (PBT), polybutyl acrylate (PBA), polyamide (PA), acrylonitrile butadiene styrene (ABS), a liquid crystal polymer (LCP), polyether ether ketone (PEEK), polybutylene succinate (PBS), urethane, and silicone. In addition, the resin to be selected may be a mixture of two or more types of resin. The resin may contain a filler (for example, a glass filler) for improvement in strength or functionality.

The sealing resin (not illustrated) injected in the inner space defined by the frame-shaped case 30 seals the space in which the substrate 11 and the semiconductor elements 12 mounted on the substrate 11 are located. The sealing resin is achieved with a thermosetting resin. Preferably, the sealing resin contains at least one of epoxy, silicone, urethane, polyimide, polyamide, and a polyamide-imide. As the sealing resin, for example, an epoxy resin containing a filler is preferable because of its insulation, heat resistance, and heat dissipation. The scaling into the inner space may be gel sealing using silicone gel or the like.

As illustrated in FIG. 2, the cooler 20 includes a case portion 21 and the top plate 22. The case portion 21 is disposed in a lower portion of the top plate 22, has a rectangular parallelepiped shape with an open upper face and a flange portion around the case portion, and has a cavity 23 therein. The cavity 23 functions as a refrigerant circulation portion through which a refrigerant such as water circulates. The case portion 21 is preferably fixed to the top plate 22 and the case 30 at a peripheral flange portion. The top plate 22 has a horizontally arranged rectangular plate shape. The case portion 21 and the top plate 22 are made of metal containing aluminum, for example.

A cooling fin 24 is disposed inside the cavity 23. The cooling fin 24 is fixed to the lower face of the top plate 22. The cooling fin 24 mainly transfers heat generated by the semiconductor element 12 to the above-described refrigerant. Note that the cooler 20 is a jacket-integrated cooler having a refrigerant flow path passing through the cooling fin 24, but may be an open-fin-type cooler, a flat-base-type cooler, or the like in which the cooling fin is exposed to the outside, and is not particularly limited.

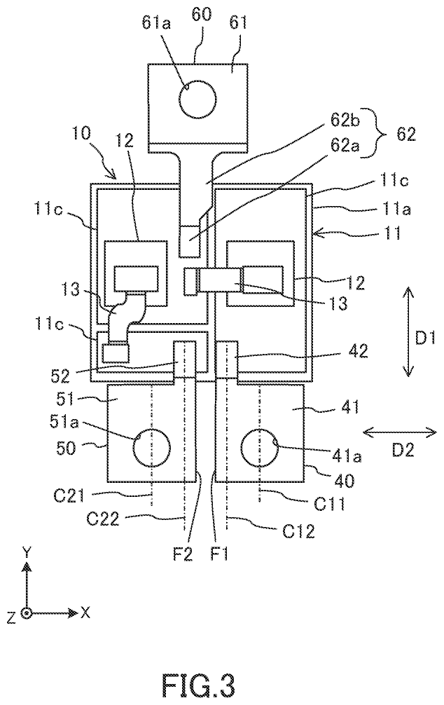

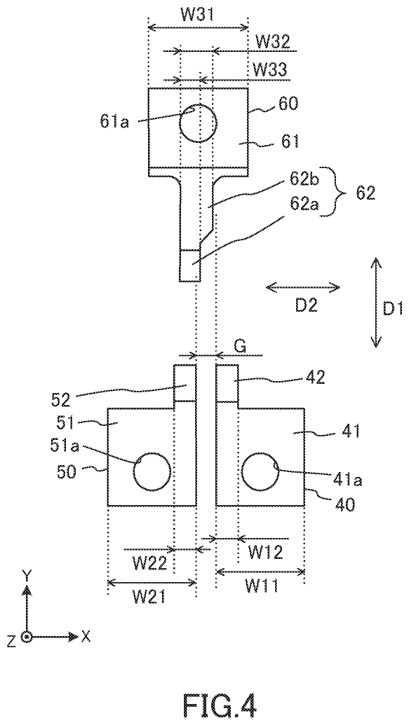

Next, the P terminal 40, the N terminal 50, and the M terminal 60 will be described in more detail with reference to FIGS. 3 and 4.

As illustrated in FIG. 3, the first narrow portion 42 of the P terminal 40 is located at an end portion of the P terminal 40 on the N terminal 50 side. The second narrow portion 52 of the N terminal 50 is located at the end of the N terminal 50 on the P terminal 40 side. The P terminal 40 and the N terminal 50 desirably have a line-symmetric shape with respect to the first direction D1.

As shown in FIG. 4, the width W12 of the first narrow portion 42 of the P terminal 40 in the second direction D2 is narrower than, for example half or less of, the width W11 of the first external connection portion 41 in the second direction D2. In addition, the width W22 of the second narrow portion 52 of the N terminal 50 in the second direction D2 is narrower than, for example half or less of, the width W21 of the second external connection portion 51 in the second direction D2.

As illustrated in FIG. 3, the center C12 of the first narrow portion 42 of the P terminal 40 in the second direction D2 is located closer to the N terminal 50 side than the center C11 of the first external connection portion 41 in the second direction D2 is. The center C22 of the second narrow portion 52 of the N terminal 50 in the second direction D2 is located closer to the P terminal 40 than the center C21 of the second external connection portion 51 in the second direction D2 is. When the center C12 of the first narrow portion 42 is located closer to the N terminal 50 side than the center C11 of the first external connection portion 41 is, and the center C22 of the second narrow portion 52 is located closer to the P terminal 40 side than the center C21 of the second external connection portion 51 is, the first narrow portion 42 may not be located at the end of the P terminal 40 on the N terminal 50 side, and the second narrow portion 52 may not be located at the end of the N terminal 50 on the P terminal 40 side.

As described above, when the width W12 of the first narrow portion 42 in the second direction D2 is equal to or less than half of the width W11 of the first external connection portion 41 in the second direction D2, and the width W22 of the second narrow portion 52 in the second direction D2 is equal to or less than half of the width W21 of the second external connection portion 51 in the second direction D2, the entire first narrow portion 42 can be located closer to the N terminal 50 side than the center C11 of the first external connection portion 41 in the second direction D2 is, and the entire second narrow portion 52 can be located closer to the P terminal 40 side than the center C21 of the second external connection portion 51 in the second direction D2 is.

The facing surfaces F1 and F2 of the P terminal 40 and the N terminal 50 facing each other, that is, the surfaces extending in the first direction D1 (Y direction) and the thickness direction (Z direction) are positioned on the same plane over the entire first direction D1. An interval between these facing surfaces F1 and F2 is a gap G illustrated in FIG. 4. Of the P terminal 40 and the N terminal 50, only the surfaces of the first narrow portion 42 and the second narrow portion 52 facing each other may be located on the same plane over the first direction D1, or only the surfaces of the first external connection portion 41 and the second external connection portion 51 facing each other may be located on the same plane over the first direction D1.

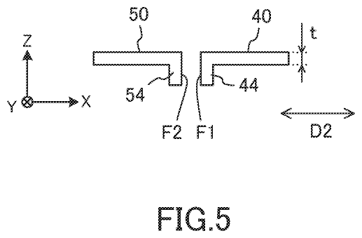

As illustrated in FIG. 5 (modification), the P terminal 40 and the N terminal 50 may have bent portions 44 and 54 bent downward (or upward) on the facing surfaces F1 and F2. In this case, the bent portions 44 and 54 of the P terminal 40 and the N terminal 50 form the above-described facing surfaces F1 and F2. Since it is desirable that the bent portions 44 and 54 of the P terminal 40 and the N terminal 50 face each other, the bent portions may be provided in the first external connection portion 41 and the second external connection portion 51, in the first narrow portion 42 and the second narrow portion 52, or over the entire P terminal 40 and N terminal 50 in first direction D1.

As illustrated in FIG. 4, the width of the third narrow portion 62 of the M terminal 60 in the second direction D2 is such that the intermediate portion 62b has a width W32 and the tip portion 62a has a narrower width W33. The widths W32 and W33 are narrower than the width W31 of the third external connection portion 61.

The position of the third narrow portion 62 in the second direction D2 is desirably the same as the position of the gap G between the P terminal 40 (facing surface F1) and the N terminal 50 (facing surface F2) in the second direction D2. In the example of FIG. 4, the positions of both the tip portion 62a and the intermediate portion 62b of the third narrow portion 62 in the second direction D2 are also the same as the position of the gap G in the second direction D2. Here, if at least a part of the third narrow portion 62 in the second direction D2 overlaps with the position of at least a part of the gap G in the second direction D2, the position of the third narrow portion 62 in the second direction D2 can be said to be the same as the position of the gap G in the second direction D2.

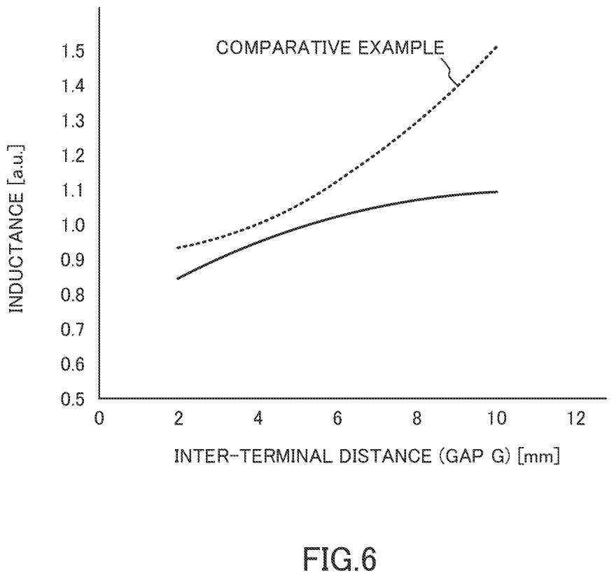

As illustrated in FIG. 6, the inter-terminal distance [mm], which is the gap G between the P terminal 40 (facing surface F1) and the N terminal 50 (facing surface F2) described above, decreases from 10 [mm] to 2 [mm] as indicated by a solid line, whereby the main circuit inductance (PN round inductance) decreases. In particular, since the inductance of the main circuit is greatly reduced at 6 [mm] or less, it can be said that the inter-terminal distance [mm] between the terminals which is the gap G is desirably 2 [mm] or more and 6 [mm] or less.

Note that the comparative example indicated by a broken line in FIG. 6 is a case where the P terminal 40 and the N terminal 50 are not line-symmetric with respect to the first direction D1, but the P terminal 40 and the N terminal 50 have the same shape in plan view, for example, in a case where the center C11 of the first external connection portion 41 of the P terminal 40 is the same as the center C12 of the first narrow portion 42, and the center C21 of the second external connection portion 51 of the N terminal 50 is the same as the center C22 of the second narrow portion 52. Also in this case, the shorter the inter-terminal distance [mm] is, the more the main circuit inductance is reduced. However, unlike the present embodiment, since the first narrow portion 42 and the second narrow portion 52 are not close to each other, the main circuit inductance is larger than that of the present embodiment.

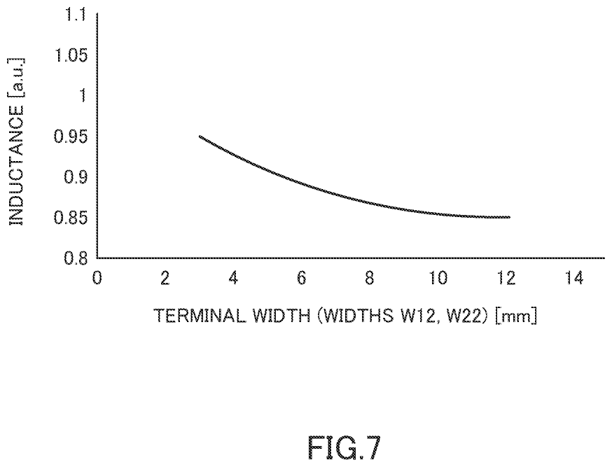

The terminal width [mm] illustrated in FIG. 7 is the width W12 in the second direction D2 of the first narrow portion 42 of the P terminal 40 and the width W22 in the second direction D2 of the second narrow portion 52 of the N terminal 50 of the present embodiment. As the terminal width [mm] increases from 2 [mm] to 12 [mm], the main circuit inductance decreases. In particular, the main circuit inductance decreases when the terminal width [mm] ranges from 2 [mm] to 10 [mm]. On the other hand, when the terminal width is wide, the area of the circuit board 11c to which the first narrow portion 42 and the second narrow portion 52 are connected increases, and thus, it can be said that the terminal width [mm] is desirably 2 [mm] or more and 10 [mm] or less.

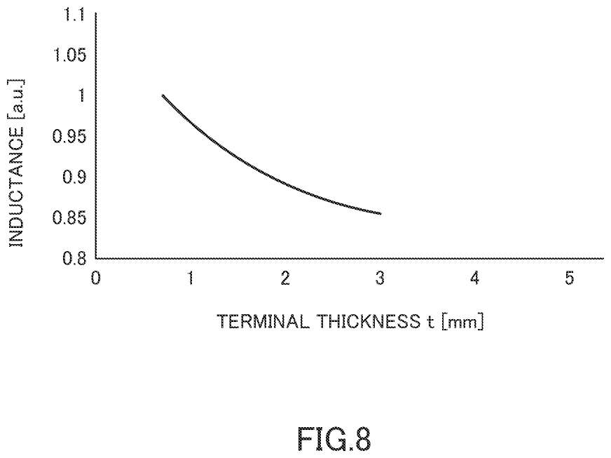

The terminal thickness t [mm] illustrated in FIG. 8 is the thickness t (see FIG. 5) in the Z direction of the P terminal 40 and the N terminal 50 of the present embodiment. The thickness t of each of the P terminal 40 and the N terminal 50 is constant as a whole, and is the same as each other. As the terminal thickness t [mm] increases from 1 [mm] (0.5 [mm]) to 3 [mm], the main circuit inductance decreases. Therefore, it can be said that the terminal thickness t [mm] is desirably 0.5 [mm] or more and 3 [mm] or less. On the other hand, as the terminal thickness t increases, more terminal material is required, or the thickness of the semiconductor device 1 decreases. Therefore, from the viewpoint of reducing the terminal thickness t and reducing the main circuit inductance, the terminal thickness t [mm] is more preferably about 0.5 [mm] or more and 1.5 [mm] or less.

In the present embodiment described above, the semiconductor device 1 includes the substrate 11 having the semiconductor element 12, and the P terminal 40 (an example of the first main terminal) and the N terminal 50 (an example of the second main terminal) located on one side (negative side in the Y direction) in the first direction D1 parallel to the mounting face (XY plane) of the semiconductor element 12 on the substrate 11. The P terminal 40 includes a first external connection portion 41 connected to the external conductor 201, and a first narrow portion 42 having a width W12 in a second direction D2 (X direction) parallel to the mounting face and orthogonal to the first direction D1 narrower than the first external connection portion 41 (width W11). The first narrow portion 42 is connected to the substrate 11. The N terminal 50 includes the second external connection portion 51 connected to the external conductor 202 and the second narrow portion 52 having the width W22 in the second direction D2 narrower than the second external connection portion 51 (width W21). The second narrow portion 52 is connected to the substrate 11. The center C12 of the first narrow portion 42 in the second direction D2 is located closer to the N terminal 50 side than the center C11 of the first external connection portion 41 in the second direction D2 is. The center C22 of the second narrow portion 52 in the second direction D2 is located closer to the P terminal 40 side than the center C21 of the second external connection portion 51 in the second direction D2 is.

As described above, the first narrow portion 42 of the P terminal 40 is positioned closer to the N terminal 50 side, and the second narrow portion 52 of the N terminal 50 is positioned closer to the P terminal 40 side, whereby the magnetic field canceling effect is enhanced, and the main circuit inductance is reduced due to the mutual inductance effect. This reduction in the main circuit inductance is more effective as the switching frequency (for example, 1.0 kHz to 10.0 kHz) of the semiconductor device 1 is higher. Therefore, this is particularly effective when the frequency tends to be particularly high, such as when a SiC-MOSFET is used as the semiconductor element 12. In addition, in the present embodiment, the first narrow portion 42 and the second narrow portion 52 approach each other, so that it is possible to secure a space on the side of the first narrow portion 42 opposite to the N terminal 50 and the side of the second narrow portion 52 opposite to the P terminal 40 in the circuit board 11c. Therefore, the substrate 11 and thus the semiconductor device 1 can be downsized. According to the present embodiment, the structure can be simplified, and the inductance can be reduced. Furthermore, by bringing the first narrow portion 42 and the second narrow portion 52 close to each other, connection portions of the first narrow portion 42 and the second narrow portion 52 with the circuit board 11c can also be brought close to each other. Therefore, it is possible to assemble the semiconductor device 1 in a short time or to detect the position of the connection portion in a short time by narrowing the operating width of the tool (for example, an ultrasonic bonding unit) for the connection.

Further, in the present embodiment, the first narrow portion 42 of the P terminal 40 is located at the end portion of the P terminal 40 on the N terminal 50 side, and the second narrow portion 52 of the N terminal 50 is located at the end portion of the N terminal 50 on the P terminal 40 side.

As a result, the main circuit inductance is further reduced due to the first narrow portion 42 and the second narrow portion 52 coming close to each other. Furthermore, in the circuit board 11c, a greater space on the side opposite to the N terminal 50 of the first narrow portion 42 and a greater space on the side opposite to the P terminal 40 of the second narrow portion 52 can be secured, so that the semiconductor device 1 can be further downsized.

In addition, in the present embodiment, the facing surfaces F1 and F2 of the P terminal 40 and the N terminal 50 facing each other are positioned entirely on the same plane in the first direction D1.

As a result, the main circuit inductance is further reduced by the mutual inductance effect on the entire facing surfaces F1 and F2 of the P terminal 40 and the N terminal 50 in the first direction D1. In a case where the facing surfaces F1 and F2 of the P terminal 40 and the N terminal 50 are not positioned on the same plane, a tolerance deviation between the P terminal 40 and the N terminal 50 is likely to occur in relation to the case 30. However, in a case where the facing surfaces F1 and F2 of the P terminal 40 and the N terminal 50 are positioned on the same plane, the semiconductor device 1 can be easily assembled.

In the present embodiment, the P terminal 40 and the N terminal 50 have a line-symmetric shape with respect to the first direction D1.

As a result, the structure of the P terminal 40 and the N terminal 50 and the structure of the semiconductor device 1 are simplified, and the main circuit inductance is reduced by the first narrow portion 42 and the second narrow portion 52 coming close to each other as described above.

In the present embodiment, the width W12 of the first narrow portion 42 of the P terminal 40 in the second direction D2 is less than or equal to half of the width W11 of the first external connection portion 41 in the second direction D2, and the width W22 of the second narrow portion 52 of the N terminal 50 in the second direction D2 is less than or equal to half of the width W21 of the second external connection portion 51 in the second direction D2.

As a result, a greater space of the circuit board 11c can be secured, so that the semiconductor device 1 can be further downsized. In addition, for example, when the first narrow portion 42 and the second narrow portion 52 are connected (for example by ultrasonic bonding or laser welding) to the substrate 11, the load is less likely to be distributed, and the connection can be facilitated.

In the present embodiment, the entire first narrow portion 42 of the P terminal 40 is located closer to the N terminal 50 side than the center C11 of the first external connection portion 41 in the second direction D2 is, and the entire second narrow portion 52 of the N terminal 50 is located closer to the P terminal 40 side than the center C21 of the second external connection portion 51 in the second direction D2 is.

As a result, the main circuit inductance is further reduced due to the first narrow portion 42 and the second narrow portion 52 coming close to each other. Furthermore, in the circuit board 11c, a greater space on the side opposite to the N terminal 50 of the first narrow portion 42 and a greater space on the side opposite to the P terminal 40 of the second narrow portion 52 can be secured, so that the semiconductor device 1 can be further downsized.

Furthermore, in the present embodiment, the semiconductor device 1 further includes an M terminal 60 (an example of the third main terminal) located on the opposite side to the P terminal 40 and the N terminal 50 in the first direction D1 with respect to the substrate 11. The M terminal 60 includes the third external connection portion 61 connected to the external conductor 203 and the third narrow portion 62 having widths W32 and W33 in the second direction D2 narrower than the third external connection portion 61 (width W31). The third narrow portion 62 is connected to the substrate 11. The position of the third narrow portion 62 in the second direction D2 is the same as the position of the gap G between the P terminal 40 and the N terminal 50 in the second direction D2.

As a result, in the second direction D2, the third narrow portion 62 is brought close to the center side which is the gap G between the P terminal 40 (the first narrow portion 42) and the N terminal 50 (the second narrow portion 52), so that the distance of the current path between the P terminal 40 and the M terminal 60 and the distance of the current path between the N terminal 50 and the M terminal 60 are brought close to each other, and an increase in inductance due to an increase in these distances can be avoided. In addition, in the substrate 11, spaces on both sides in the second direction D2 of the third narrow portion 62 can be secured, so that the semiconductor device 1 can be further downsized. In addition, it is possible to assemble the semiconductor device 1 in a short time or to detect the position of the connection portion in a short time by narrowing the operating width of the tool (for example, an ultrasonic bonding unit). In addition, the P terminal 40, the N terminal 50, and the M terminal 60 can have a favorable appearance in plan view.

Hereinafter, the invention described in the claims of the originally filed application will be additionally described.

### Supplementary Note 1

A semiconductor device including:
a substrate including a semiconductor element; and
a first main terminal and a second main terminal located on one side in a first direction parallel to a mounting face of the semiconductor element on the substrate, in which
the first main terminal includes a first external connection portion connected to an external conductor and a first narrow portion connected to the substrate, the first narrow portion having a width in a second direction parallel to the mounting face and orthogonal to the first direction smaller than a width of the first external connection portion,
the second main terminal includes a second external connection portion connected to an external conductor and a second narrow portion connected to the substrate, the second narrow portion having a width in the second direction smaller than a width of the second external connection portion,
a center of the first narrow portion in the second direction is located closer to the second main terminal than a center of the first external connection portion in the second direction is, and
a center of the second narrow portion in the second direction is located closer to the first main terminal than a center of the second external connection portion in the second direction is.

### Supplementary Note 2

The semiconductor device according to Supplementary note 1, in which
the first narrow portion of the first main terminal is located at an end portion of the first main terminal on the second main terminal side, and
the second narrow portion of the second main terminal is located at an end portion of the second main terminal on the first main terminal side.

### Supplementary Note 3

The semiconductor device according to Supplementary note 2, in which
opposing surfaces of the first main terminal and the second main terminal facing each other are located on the same plane over the first direction.

### Supplementary Note 4

The semiconductor device according to Supplementary note 1, in which the first main terminal and the second main terminal have a line-symmetric shape with respect to the first direction.

### Supplementary Note 5

The semiconductor device according to Supplementary note 1, in which the width of the first narrow portion in the second direction is equal to or less than a half of the width of the first external connection portion in the second direction, and the width of the second narrow portion in the second direction is equal to or less than a half of the width of the second external connection portion in the second direction.

### Supplementary Note 6

The semiconductor device according to Supplementary 5, in which
the entirety of the first narrow portion is located closer to the second main terminal than the center of the first external connection portion in the second direction is, and
the entirety of the second narrow portion is located closer to the first main terminal than the center of the second external connection portion in the second direction is.

### Supplementary Note 7

The semiconductor device according to any one of Supplementary notes 1 to 6, further including
a third main terminal located on a side opposite to the first main terminal and the second main terminal in the first direction with respect to the substrate, in which
the third main terminal includes a third external connection portion connected to an external conductor and a third narrow portion connected to the substrate, the third narrow portion having a width in the second direction smaller than a width of the third external connection portion, and
a position of the third narrow portion in the second direction is the same as a position of a gap between the first main terminal and the second main terminal in the second direction.

As described above, the present invention has an effect of simplifying the structure and reducing the inductance in the semiconductor device, and is useful for, for example, a power semiconductor device.

What is claimed is:

1. A semiconductor device, comprising:
a substrate including a semiconductor element provided on a mounting face of the substrate, the substrate having one side and another side that are opposite to each other in a first direction parallel to the mounting face; and
a first main terminal and a second main terminal that are located at the one side of the substrate, the first main terminal and the second main terminal facing each other in a second direction parallel to the mounting face and orthogonal to the first direction, wherein
the first main terminal includes a first external connection portion connected to an external conductor and a first narrow portion connecting the first external connection portion to the substrate in the second direction, the first narrow portion having a width smaller than a width of the first external connection portion,
the second main terminal includes a second external connection portion connected to an external conductor and a second narrow portion connecting the second external connection portion to the substrate in the second direction, the second narrow portion having a width smaller than a width of the second external connection portion,
in the second direction, a center of the first narrow portion is located closer to the second main terminal than is a center of the first external connection portion, and
in the second direction, a center of the second narrow portion is located closer to the first main terminal than is a center of the second external connection portion.

2. The semiconductor device according to claim 1, wherein
the first narrow portion of the first main terminal is connected to one side of the first main terminal in the second direction at an end thereof that is closer to the second main terminal than is a center thereof, and
the second narrow portion of the second main terminal is connected to one side of the second main terminal in the second direction at an end thereof that is closer to the first main terminal than is a center thereof.

3. The semiconductor device according to claim 2, wherein
a surface of the first main terminal parallel to the first direction and a surface of the second main terminal parallel to the first direction, which face each other, are each flat.

4. The semiconductor device according to claim 1, wherein
the first main terminal and the second main terminal have a line-symmetric shape with respect to a line in the first direction.

5. The semiconductor device according to claim 1, wherein
the width of the first narrow portion in the second direction is equal to or less than half of the width of the first external connection portion in the second direction, and
the width of the second narrow portion in the second direction is equal to or less than half of the width of the second external connection portion in the second direction.

6. The semiconductor device according to claim 5, wherein
the entirety of the first narrow portion is located closer to the second main terminal than is the center of the first external connection portion in the second direction, and
the entirety of the second narrow portion is located closer to the first main terminal than is the center of the second external connection portion in the second direction.

7. The semiconductor device according to claim 1, further comprising
a third main terminal located on the other side of the substrate opposite in the first direction to the one side of the substrate where the first main terminal and the second main terminal are disposed, wherein
the third main terminal includes a third external connection portion connected to an external conductor and a third narrow portion connected to the third external connection portion and to the substrate, the third narrow portion having a width in the second direction smaller than a width of the third external connection portion, and
a position of the third narrow portion in the second direction overlaps in the first direction a position of a gap between the first main terminal and the second main terminal in the second direction.
